(19) United States
(12) Patent Application Publication
(10) Pub. No.: US 2002/0043613 A1
(43) Pub. Date: Apr. 18, 2002

(54) Illuminance sensor chip and illuminance sensor incorporating the same

(76) Inventors: Nobuaki Suzuki, Kyoto (JP); Shinichi Suzuki, Kyoto (JP)

Correspondence Address: MICHAEL D. BEDNAREK, SHAW PITTMAN LLP, 1650 TYSONS BOULEVARD, MCLEAN, VA, 22102, US

(21) Appl. No.: 09/949,728

(22) Filed: Sep. 12, 2001

(30) Foreign Application Priority Data
Sep. 12, 2000 (JP) 2000-276018

(51) Int. Cl. H01L 31/06

(52) U.S. Cl. 250/214.1; 257/462; 257/464

(57) ABSTRACT

An illuminance sensor chip includes a first semiconductor layer, and a second semiconductor layer joined to the first semiconductor layer. When light is incident on the junction between the first semiconductor layer and the second semiconductor layer, the sensor chip outputs an electric signal in accordance with an amount of light incident on the junction. The thickness D of the second semiconductor layer is set to 2-4 μm for example so that the peak sensitivity wavelength in the spectral sensitivity characteristics lies in a visible light wavelength range. An illuminance sensor further includes, besides the above-described illuminance sensor chip, an additional illuminance sensor chip which is identical or generally identical to the first-mentioned illuminance sensor chip in spectral sensitivity characteristics. The additional illuminance sensor chip is provided with a visible light shielding portion for absorbing visible light. The illuminance is calculated based on the outputs from the illuminance sensor and the additional illuminance sensor.

### TECHNICAL FIELD

The present invention relates to an illuminance sensor chip used for detecting ambient brightness and to techniques related therewith.

### BACKGROUND ART

An illuminance sensor for detecting ambient brightness is conventionally used for various purposes. In a camera, for example, the necessity for the use of a flash is determined based on an output from such an illuminance sensor.

An illuminance sensor includes an illuminance sensor chip which comprises a phototransistor for example. The illuminance sensor chip outputs an electric signal in accordance with the received amount of light. A conventionally used illuminance sensor chip has spectral sensitivity characteristics (which represent the relationship between wavelength and output) in which the peak sensitivity wavelength is 800-950 nm. Thus, the illuminance sensor chip outputs an electric signal mainly in accordance with the received amount of infrared rays. That is, the illuminance sensor incorporating such an illuminance sensor chip outputs an electric signal for representing the ambient brightness in accordance with the amount of infrared rays.

On the other hand, a mobile phone utilizes a reflective-type liquid crystal display apparatus for displaying images. In the reflective-type liquid crystal display apparatus, the brightness of the display depends on the amount of visible rays of the incident light. Therefore, when the environment of the display apparatus is sufficiently bright, it is possible to clearly show the images utilizing external light only. However, when the environment of the display apparatus is dark, it is not possible to clearly show images by the external light only. Therefore, when the amount of external light is insufficient, the light source need be turned on to compensate for the amount of visible rays.

In this case, an illuminance sensor may be utilized for detecting the ambient brightness of the liquid crystal display apparatus, and whether or not the light source is to be turned on may be determined based on the output from the illuminance sensor.

As described above, the brightness of the display of a reflective-type liquid crystal display apparatus is determined depending on the amount of visible rays of the incident light. Therefore, it is ideal that the ambient brightness of the liquid crystal display apparatus is detected based on the amount of visible rays for determining whether or not the light source is to be turned on. However, the prior art illuminance sensor chip has spectral sensitivity characteristics in which the peak sensitivity wavelength lies in the infrared range. On the other hand, the wavelength which can be most efficiently perceived by the human eyes in photopic vision (i.e. the peak wavelength in the spectral luminous efficiency) is about 555 nm, which largely deviates from the peak sensitivity wavelength of the prior art illuminance sensor chip. Therefore, the prior art illuminance sensor chip may not be suitably for used for an illuminance sensor of the above-described mobile phone. There exists a method for providing an infrared-shielding filter to the illuminance sensor so that the sensor selectively receives visible light. However, it is technically difficult to shield infrared rays without decreasing the amount of visible light. Further, such a method is costly due to the provision of the infrared-shielding filter.

### DISCLOSURE OF THE INVENTION

It is an object of the present invention to provide a technique which enables the measurement of illuminance reflecting the amount of visible light in a cost-effective manner.

In accordance with a first aspect of the present invention, there is provided an illuminance sensor chip comprising a first semiconductor layer, and a second semiconductor layer joined to the first semiconductor layer to provide a junction between the first semiconductor layer and the second semiconductor layer. The sensor chip outputs an electric signal in accordance with an amount of light incident on the junction through the second semiconductor layer.

The second semiconductor layer has a thickness which is set to provide spectral sensitivity characteristics based on the output of the electric signal and having a peak sensitivity wavelength lying in a visible light wavelength range.

Preferably, the thickness of the second semiconductor layer may be no more than 4 μm. More preferably, the thickness of the second semiconductor layer may be no less than 2 μm.

In a preferred embodiment, the peak sensitivity wavelength may be 580-600 nm.

Preferably, the second semiconductor layer may be formed of silicon.

In a preferred embodiment, the illuminance sensor chip is a phototransistor. Preferably, the phototransistor includes an NPN-junction. In such a case, the second semiconductor layer is a P-type semiconductor layer.

In accordance with a second aspect of the present invention, there is provided an illuminance sensor including an illuminance sensor chip.

The illuminance sensor chip comprises a first semiconductor layer, and a second semiconductor layer joined to the first semiconductor layer to provide a junction between the first semiconductor layer and the second semiconductor layer. The sensor chip outputs an electric signal in accordance with an amount of light incident on the junction through the second semiconductor layer.

The second semiconductor layer has a thickness which is set to provide spectral sensitivity characteristics based on the output of the electric signal and having a peak sensitivity wavelength lying in a visible light wavelength range.

In a preferred embodiment, the second semiconductor layer is formed of silicon and has a thickness of 2-4 μm.

In a preferred embodiment, the illuminance sensor chip is a phototransistor having an NPN-junction. In such a case, the second semiconductor layer is a P-type semiconductor layer.

In a preferred embodiment, the illuminance sensor further comprises an additional illuminance sensor chip which is identical or generally identical to the illuminance sensor chip in spectral sensitivity characteristics, and

a visible light shielding portion for absorbing visible light before the incident light reaches the additional sensor chip.

The additional illuminance sensor chip may be sealed in a black resin package. In this case, the resin package constitutes the visible light shielding portion.

In a preferred embodiment, the illuminance sensor chip may be sealed in a first transparent resin package, whereas the additional illuminance sensor chip may be sealed in a second black resin package. In this case, the second resin package constitutes the visible light shielding portion.

Preferably, the first resin package and the second resin package may be sealed in a third transparent resin package.

The visible light shielding portion may comprise a visible light shielding filter for covering the second semiconductor layer.

In accordance with a third aspect of the present invention, there is provided an illuminance measuring apparatus comprising a first and a second illuminance sensor chips each comprising a first semiconductor layer, and a second semiconductor layer joined to the first semiconductor layer to provide a junction between the first semiconductor layer and the second semiconductor layer, each of the sensor chips outputting an electric signal in accordance with an amount of light incident on the respective junction through the respective second semiconductor layer,

a visible light shielding portion for absorbing visible light before the incident light reaches the junction of the second illuminance sensor chip, and

an illuminance calculation section for calculating an illuminance based on the outputs from the first and the second illuminance sensor chips.

Preferably, the second semiconductor layer of the first illuminance sensor chip may be formed of silicon and has a thickness of 2-4 μm. More preferably, the second illuminance sensor chip may be identical or generally identical to the first illuminance sensor chip in spectral sensitivity characteristics.

In a preferred embodiment, the illuminance calculation section may calculate the illuminance based on a signal corresponding to a difference between the output from the first illuminance sensor chip and the output from the second illuminance sensor chip.

In accordance with a fourth aspect of the present invention, there is provided an illuminance measuring method using a first and a second illuminance sensor chips.

Each of the first and the second illuminance sensor chips comprises a first semiconductor layer, and a second semiconductor layer joined to the first semiconductor layer to provide a junction between the first semiconductor layer and the second semiconductor layer, each of the sensor chips outputting an electric signal in accordance with an amount of light incident on a respective one of the junctions through a respective one of the second semiconductor layers.

The method comprises calculating the illuminance based on the outputs from the first and the second illuminance sensor chips.

In a preferred embodiment, the first illuminance sensor chip and the second illuminance sensor chip are identical or generally identical to each other in spectral sensitivity characteristics, and

visible light is absorbed before the incident light reaches the second illuminance sensor chip.

In a preferred embodiment, the illuminance is calculated based on a signal corresponding to a difference between the output from the first illuminance sensor chip and the output from the second illuminance sensor chip.

### BRIEF DESCRIPTION OF THE DRAWINGS

FIG. 1 is a perspective view, which is partially schematic, showing an illuminance measuring apparatus according to a first embodiment of the present invention.

FIG. 2 is a sectional view taken on lines II-II in FIG. 1.

FIG. 3 is a sectional view of an illuminance sensor chip.

FIG. 4 is a graph showing spectral sensitivity characteristics of the illuminance sensor chip according to the present invention and of prior art illuminance sensor chips which differ from the sensor chip of the present invention in thickness of the P-type semiconductor layer.

FIG. 5 is a graph showing the results of measurement for determining the thickness of the P-type semiconductor layer of an illuminance sensor chip.

FIG. 6 is a perspective view, which is partially schematic, showing an illuminance measuring apparatus according to a second embodiment of the present invention.

FIG. 7 is a graph showing spectral sensitivity characteristics of the two sensors shown in FIG. 6.

FIG. 8 is a perspective view, which is partially schematic, showing an illuminance measuring apparatus according to a third embodiment of the present invention.

FIG. 9 is a sectional view taken on lines IX-IX in FIG. 8.

### BEST MODE FOR CARRYING OUT THE INVENTION

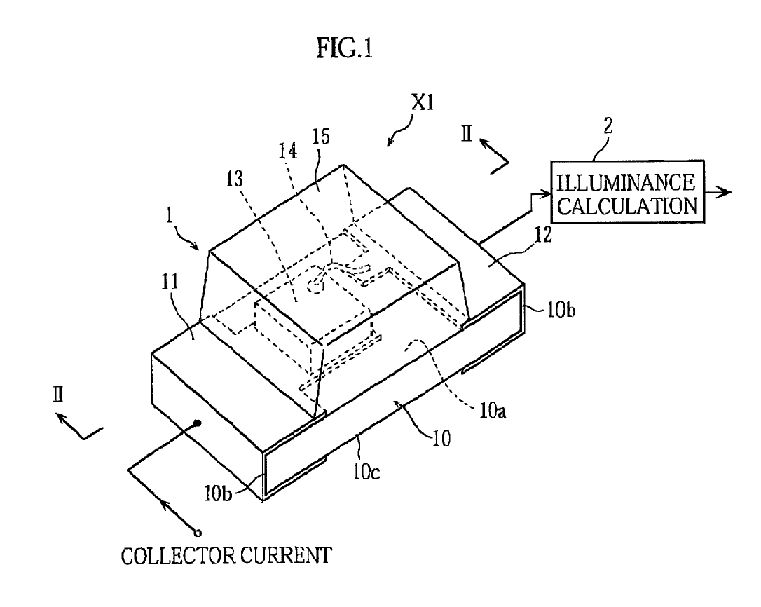

FIG. 1 illustrates an illuminance measuring apparatus X1 according to a first embodiment of the present invention, which may be used as incorporated in a mobile phone for example. In the mobile phone, whether or not the light source of the reflective-type liquid crystal display apparatus is turned on is determined based on the illuminance measured by the illuminance measuring apparatus X1.

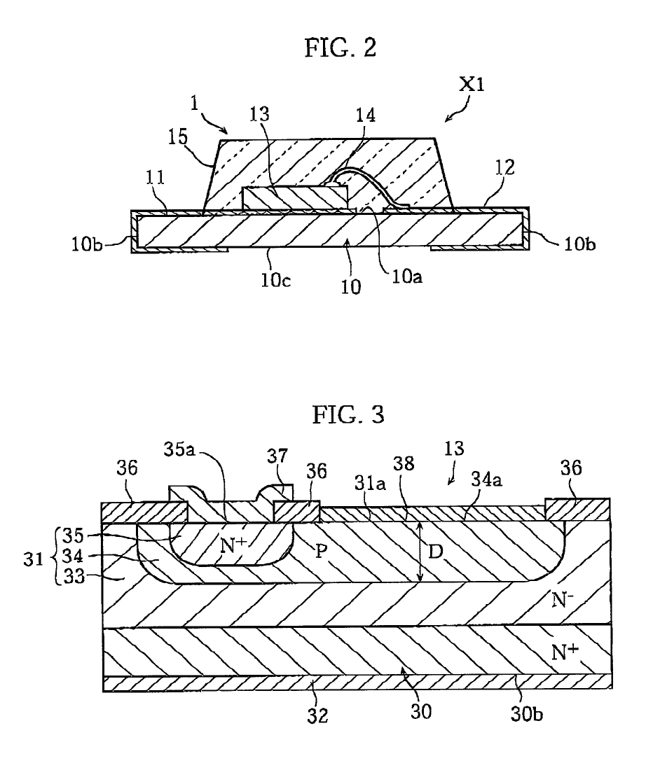

The illuminance measuring apparatus X1 includes an illuminance sensor 1 and an illuminance calculation section 2. The illuminance sensor 1 is so designed as to mainly receive visible light. As shown in FIGS. 1 and 2, the illuminance sensor 1 includes an insulating substrate 10, a first electrode 11, a second electrode 12 and a first illuminance sensor chip 13.

The insulating substrate 10 may be formed of an insulating material such as glass-fiber-reinforced epoxy resin into a generally rectangular configuration. Each of the first and the second electrodes 11, 12 extends from the upper surface 10a through a corresponding one of side surfaces 10b onto the lower surface 10c of the insulating substrate 10. The first and the second electrodes 11, 12 may be provided by forming a metal film (e.g. Al film) by vapor deposition followed by etching.

The illuminance sensor chip 13 is mounted on the first electrode 11. The illuminance sensor chip 13 is bonded to the first electrode 11 via a conductive adhesive for example. The illuminance sensor chip 13 is connected to the second electrode 12 via a wire 14. The wire 14 may be a gold wire for example. The connection between the illuminance sensor chip 13 and the second electrode 12 via the wire 14 may be performed with a known wire bonder.

The illuminance sensor chip 13 and the wire 14 are sealed by a resin package 15. The resin package 15 may be made of epoxy resin for example to be transparent for allowing passage of visible light. The resin package 15 may be formed by transfer molding for example.

The illuminance sensor chip 13 has spectral sensitivity characteristics in which the peak sensitivity wavelength lies in the visible light wavelength range i.e. in the wavelength range of 380-780 nm, preferably in the range of 580-600 nm. As shown in FIG. 3, the illuminance sensor chip 13 comprises a phototransistor including an N+-type silicon substrate 30 and an NPN junction 31 formed on the substrate. The N+-type silicon substrate 30 has a lower surface 30b on which a collector electrode 32 is formed. The collector electrode 32 may be formed of Au by vapor deposition for example.

The NPN junction 31 comprises an N−-type semiconductor layer 33 as a first semiconductor layer, a P-type semiconductor layer 34 as a second semiconductor layer, and an N+-type semiconductor layer 35.

The N−-type semiconductor layer 33, which functions as the collector, is formed over the entire upper surface of the silicon substrate 30.

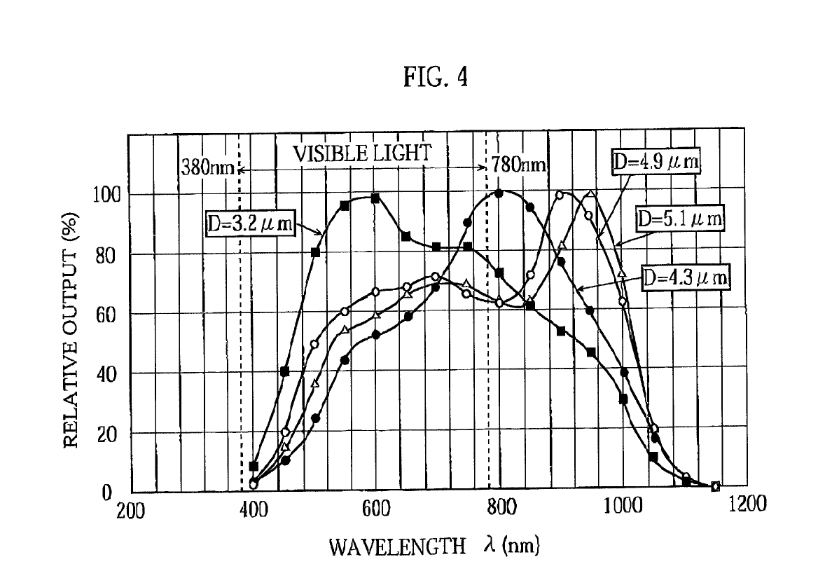

The P-type semiconductor layer 34, which functions as the base, is built in the N−-type semiconductor layer 33. The thickness D of the P-type semiconductor layer 34 is so set that the peak sensitivity wavelength in its spectral sensitivity characteristics lies in the visible light wavelength range (e.g. D=3.2 μm as in FIG. 4). To obtain such spectral sensitivity characteristics, the thickness D of the P-type semiconductor layer 34 is set to 2-4 μm, preferably to 2.5-3.5 μm. The relationship between the thickness D of the P-type semiconductor layer 34 and the peak sensitivity wavelength will be considered later.

The N+-type semiconductor layer 35, which functions as the emitter, is built in the P-type semiconductor layer 34.

The NPN junction 31 may be formed by a wafer process for an N+-type silicon wafer. In the wafer process, the N−-type semiconductor layer 33 may be formed by vapor phase epitaxial growth, and the P-type semiconductor layer 34 and the N+-type semiconductor layer 35 may be formed by impurity diffusion. The P-type semiconductor layer 34 may be formed using e.g. boron as the dopant. The N+-type semiconductor layer 35 may be formed using e.g. phosphorus as the dopant.

To form a P-type semiconductor layer 34 having a thickness D of 2-4 μm using B2H6 as the impurity source (for using boron as the dopant), the impurity diffusion need be performed under the diffusion conditions of 1100-1200° C. and 90-110 minutes for heating.

The NPN junction 31 has an upper surface 31a on which an insulating layer 36 is formed. The insulating layer 36 covers the upper surface 31a at respective boundaries of the semiconductor layers 33, 34, 35. Therefore, most portions of the P-type semiconductor layer 34 and the N+-type semiconductor layer 35 are exposed through the insulating layer 36. The insulating layer 36 may be formed of SiO2 for example.

The exposed surface 34a of the P-type semiconductor layer 34 is covered with a protective layer 38. The protective layer 38 may be formed of SiN for example. On the other hand, the exposed surface 35a of the N+-type semiconductor layer 35 is covered with an emitter electrode 37. The emitter electrode 37 may be formed of Al for example.

In the illuminance sensor 1, when light is incident on the P-type semiconductor layer 34 of the illuminance sensor chip 13 through the resin package 15, an electric signal (emitter current) corresponding to the received amount of light is outputted. Due to the incidence of light on the P-type semiconductor layer 34, carriers are generated to provide a base current. Thus, a collector current is supplied to the N−-type semiconductor layer 33 from an external power source (not shown) connected to the first electrode 11 through the collector electrode 32. The collector current is combined with the base current to be outputted from the emitter electrode 37 as an emitter current which is inputted to the illuminance calculation section 2 via the wire 14 and the second electrode 12.

The illuminance calculation section 2 calculates the illuminance based on the emitter current outputted from the illuminance sensor 1. The illuminance calculation section 2 may comprise a CPU, a ROM and a RAM for example.

The ROM stores a table indicating the relationship between the emitter current and the illuminance, and a program for calculating the illuminance based on the table. The CPU and the RAM execute the program using the emitter current as a variable to calculate the illuminance in accordance with the emitter current (received amount of light).

The inventors of the present invention examined spectral sensitivity characteristics of four illuminance sensor chips which differ from each other only in thickness D of the P-type semiconductor layer 34. The spectral sensitivity characteristics were measured with respect to the illuminance sensor having configuration as shown in FIGS. 1 and 2. The results are shown in FIG. 4. It is to be noted that the P-type semiconductor layer was formed by diffusing boron as the dopant.

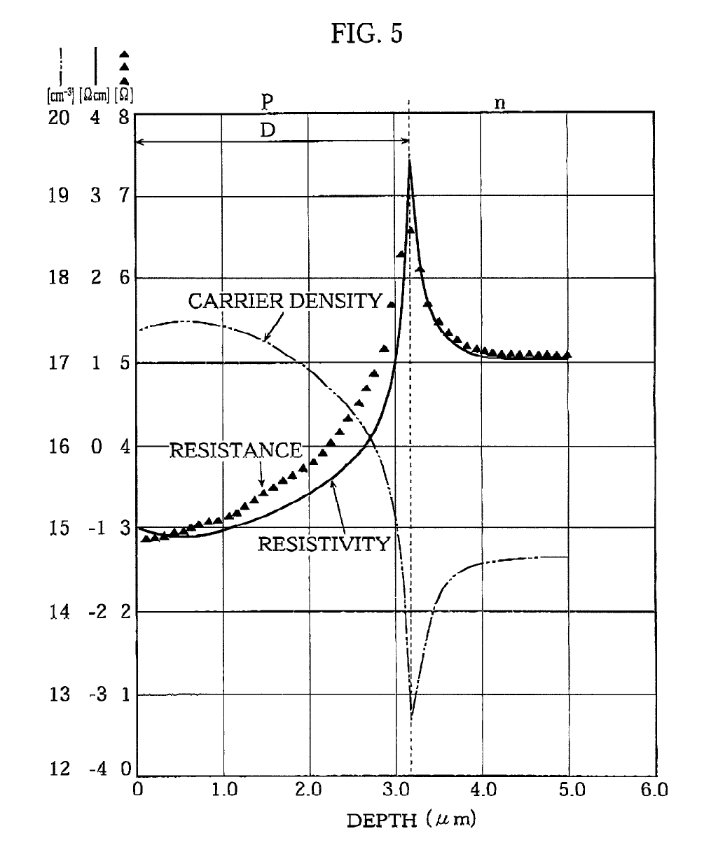

The thickness of the P-type semiconductor layer is determined by measuring resistance (Ω), resistivity (Ωcm) and carrier density (cm−3) at positions which differ from each other in depth from the upper surface 34a of the P-type semiconductor layer 34. Specifically, the depth where respective absolute values of these parameters become maximum is defined as the thickness of the P-type semiconductor layer 34. In FIG. 5, the resistance, the resistivity, and the carrier density are indicated by black triangles, a solid line, and a chain line, respectively. In this example, the thickness of the P-type semiconductor layer is 3.2 μm. As a result of such measurement, it was found that the respective P-type semiconductor layers of the four illuminance sensor chips had thicknesses of 3.2 μm, 4.3 μm, 4.9 μm, and 5.1 μm, respectively.

As can be seen from FIG. 4, when a P-type semiconductor layer has a relatively small thickness, its peak sensitivity wavelength lies in the visible light wavelength range. As the thickness of a P-type semiconductor layer increases, the peak sensitivity wavelength shifts toward the longer wavelength side. This indicates that, by adjusting the thickness of the P-type semiconductor layer, it is possible to enhance the visible light sensitivity of the illuminance sensor chip (illuminance sensor) so that its peak sensitivity wavelength lies in the visible light wavelength range. Specifically, as can be inferred from FIG. 4, it is suitable to set the thickness of a P-type semiconductor to no more than 4 μm. Further, by setting the thickness of a P-type semiconductor layer to 3.2 μm, it is possible to provide an illuminance sensor chip (illuminance sensor) whose peak sensitivity wavelength lies in the range of 580-600 nm.

On the other hand, it is preferable that the minimum value of the P-type semiconductor layer is made 2 μm. This is because, when the thickness D of the P-type semiconductor layer 34 is excessively small, it is difficult to provide a proper NPN junction. Specifically, for forming the N+-type semiconductor layer 35 by impurity diffusion, it is difficult to diffuse the impurity only in the P-type semiconductor layer 34 while at the same time preventing the impurity diffusion into the N−-type semiconductor layer 33, if the thickness of the P-type semiconductor layer 34 is excessively small.

In this way, by the adjusting the thickness D of the P-type semiconductor layer 34, the peak sensitivity wavelength of the illuminance sensor chip 13 lies in the visible light wavelength range. Further, by appropriately setting the thickness D of the P-type semiconductor layer, the peak sensitivity wavelength of the sensor can be made close to the peak wavelength in the spectral luminous efficiency in photopic vision. Therefore, the variation of the output (emitter current) from the illuminance sensor chip 13 (illuminance sensor 1) corresponds to the human sensitivity of brightness. As a result, the measuring apparatus X1 measures the illuminance which corresponds to the brightness human feels.

The illuminance sensor chip 13 is advantageous in terms of the manufacturing cost because its peak sensitivity wavelength lies in the visible light wavelength range. Specifically, first of all, the sensor chip is cost-effective because the provision of an infrared-shielding filter is not necessary. Secondly, in the case where the P-type semiconductor layer 34 is formed by impurity diffusion for example, the thickness of the P-type semiconductor layer 34 can be adjusted just by adjusting the diffusion condition. Therefore, it is possible to make the sensor chip using the existing manufacturing line without making modification, which is cost-effective.

The illuminance measuring apparatus X1 may be used in a reflective-type liquid crystal apparatus of a mobile phone for example to determine whether or not the light source is turned on. As described above, the illuminance measuring apparatus X1 measures the illuminance so as to correspond to human sensitivity of brightness. When human feels it is bright, the display of the liquid crystal display apparatus looks bright so that the displayed images can be viewed easily. On the other hand, when human feels it is dark, the display of the liquid crystal display apparatus looks dark so that it is difficult to view the displayed image. Therefore, by measuring the illuminance so as to correspond to the brightness which human senses, it is possible to turn on the light source only under the circumstances where the displayed image cannot be viewed easily. As a result, it is possible to prevent unnecessary lighting of the light source, which leads to a decrease in power consumption.

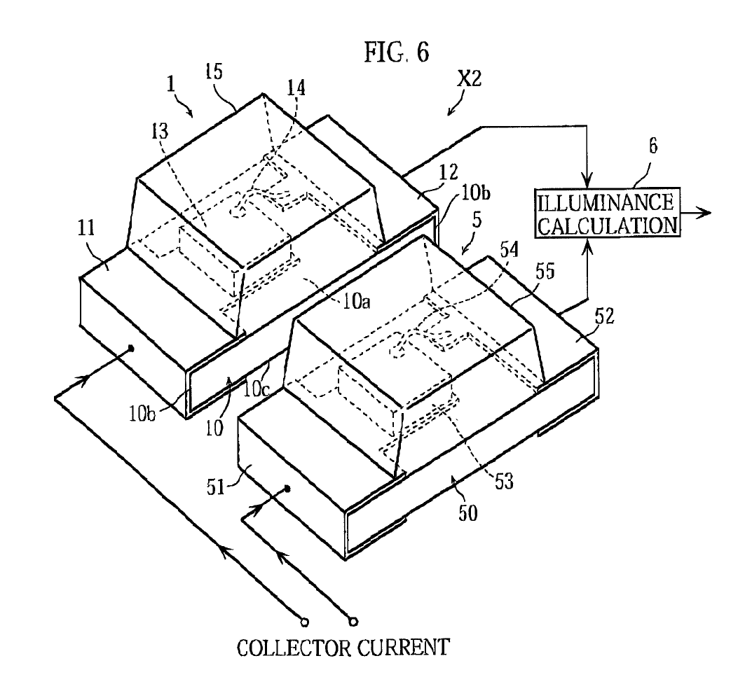

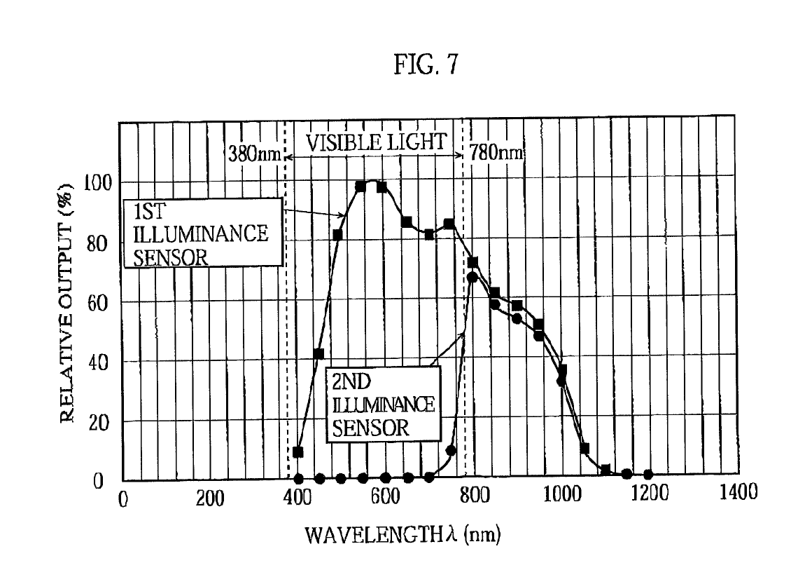

Next, an illuminance measuring apparatus X2 according to a second embodiment of the present invention will be described with reference to FIGS. 6 and 7.

The illuminance measuring apparatus X2 includes a first illuminance sensor 1, a second illuminance sensor 5 and an illuminance calculation section 6. The first illuminance sensor 1 is identical to the illuminance sensor of the first embodiment of the present invention. Therefore, the illuminance sensor 1 outputs an electric signal (emitter current) mainly in accordance with the received amount of visible light. The emitter current is inputted to the illuminance calculation section 6 via the wire 14 and the second electrode 12. In FIG. 6, the structural elements of the first illuminance sensor 1 are designated by the same reference signs as those used for those of the illuminance sensor shown in FIGS. 1 and 2.

The structure and operation of the second illuminance sensor 5 are basically identical to those of the first illuminance sensor 1. Specifically, the second illuminance sensor 5 includes a mounting substrate 50, a first and a second electrodes 51, 52, an illuminance sensor chip 53, a wire 54 and a resin package 55.

However, the resin package 55 selectively absorbs visible light. Specifically, the resin package 55 is made black by adding a black pigment to epoxy resin for example. For the black pigment, use may be made of black iron oxide, CdTe or carbon black.

The second illuminance sensor chip 53 has spectral sensitivity characteristics which is identical or generally identical to that of the first illuminance sensor chip 13 (See D=3.2 μm in FIG. 4), and the same one as the first illuminance sensor chip 13 may be used for example.

In the second illuminance sensor 5, the illuminance sensor chip 53 is sealed in a resin package 55 which is colored black. Therefore, visible light is absorbed by the resin package 55 so that infrared rays selectively reach the illuminance sensor chip 53. Therefore, as shown in FIG. 7, the second illuminance sensor 5 outputs an electric signal (emitter current) in accordance with the received amount of infrared rays. The emitter current is inputted to the illuminance calculation section 6 via he wire 54 and the second electrode 52 (See FIG. 6).

Particularly, the illuminance sensor chip 53 used for the second illuminance sensor 5 has spectral sensitivity characteristics which are identical to or generally identical to that of the first illuminance sensor 1. Therefore, as clearly shown in FIG. 7, the spectral sensitivity characteristics of the second illuminance sensor 5 generally coincide with that of the first illuminance sensor 1 in the infrared region.

In the illuminance calculation section 6, the output (emitter current) from the second illuminance sensor 5 is subtracted from the output (emitter current) from the first illuminance sensor 1 to calculate the illuminance based on the difference. The illuminance calculation section 6 may comprise a difference amplifier, a CPU, a ROM and a RAM.

The difference amplifier operates to subtract the emitter current of the second illuminance sensor 5 from the emitter current of the first illuminance sensor 1 for outputting.

The CPU, the ROM and the RAM calculate the illuminance based on the output from the difference amplifier. The ROM stores a table indicating the relationship between the output and the illuminance, and a program for calculating the illuminance based on the table for example. The CPU and the RAM execute the program using the output from the difference amplifier as a variable to calculate the illuminance in accordance with the output.

As described with reference to FIG. 7, in the illuminance measuring apparatus X2, the spectral sensitivity characteristics of the second illuminance sensor 5 generally coincides with that of the first illuminance sensor 1 in the infrared region. Therefore, the difference obtained by subtracting the emitter current of the second illuminance sensor 5 from the emitter current of the first illuminance sensor 1 generally coincide with the amount of visible light. Therefore, by calculating the illuminance utilizing the difference between the respective emitter currents of the first and the second illuminance sensors 1, 5, it is possible to measure the illuminance correspondingly to human sensitivity.

In the illuminance sensor chip 53, a visible light shielding filter may be provided to cover the P-type semiconductor layer (See FIG. 3). In such a case, the resin package 55 may be transparent.

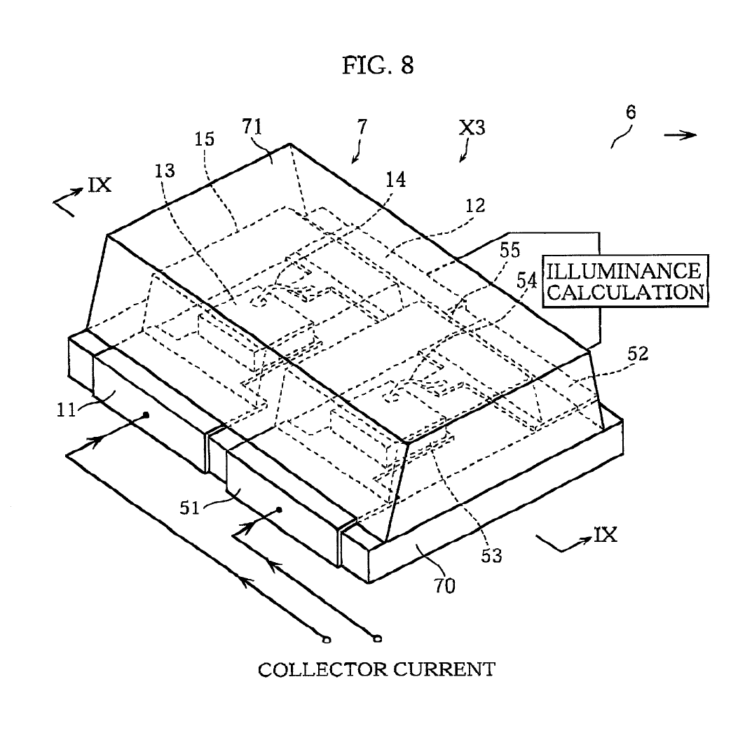

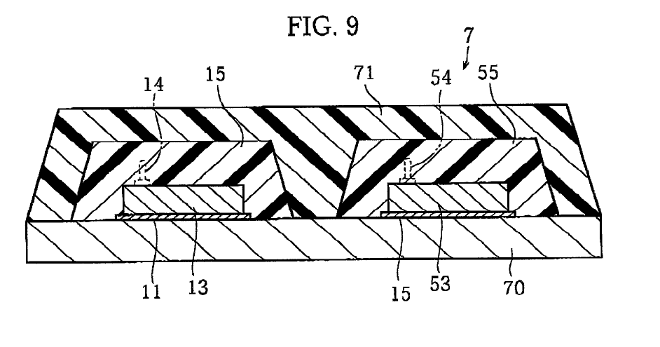

Next, an illuminance measuring apparatus according to a third embodiment of the present invention will be described with reference to FIGS. 8 and 9.

In the illuminance measuring apparatus X3, sensors which correspond to the illuminance sensors 1, 5 shown in FIG. 6 are provided on a common insulating substrate 70. In FIGS. 8 and 9, the structural elements which are identical to those of the illuminance sensors 1, 5 shown in FIG. 6 are designated by the same reference signs as those used for the illuminance sensors 1, 5.

The insulating substrate 70 is formed with first electrodes 11, 51 and second electrodes 12, 52. Illuminance sensor chips 13, 53 are mounted on the first electrodes 11, 51, respectively. The illuminance sensor chips 13, 53 are identical or generally identical to each other in spectral sensitivity characteristics, and preferably also identical in design. The illuminance sensor chips 13, 53 are connected to the second electrodes 12, 52 via wires 14, 54, respectively.

The illuminance sensor chip 13 and the wire 14 are sealed in a first resin package 15. The illuminance sensor chip 53 and the wire 54 are sealed in a second resin package 55. The first resin package 15 may be transparent, whereas the second resin package 55 may be made black for example. The first and the second resin packages 51, 55 are covered with a third package 71. The third resin package 71 is transparent.

In the illumination calculation section 6, the output of the illuminance sensor chip 53 is subtracted from the output of the illuminance sensor chip 13 to calculate the illuminance based on the difference. The illumination calculation section 6 may comprise a difference amplifier, a CPU, a ROM and a RAM.

Since the illuminance measuring apparatus X3 is identical to the illuminance measuring apparatus X2 in basic structure and operation, the illuminance measuring apparatus X3 can obtain the same advantages as those of the illuminance measuring apparatus X2.

In the illuminance sensor 7, the third resin package 71 can be dispensed with. The illuminance sensor chip 53 may be provided with a visible light shielding filter for covering the P-type semiconductor layer (See FIG. 3). In such a case, the resin package 55 may be made transparent, or the illuminance sensor chips 13, 53 may be sealed in a single transparent resin package.

In the present invention, the illuminance sensor chip may comprise a PNP-type phototransistor. In such a case, by adjusting the thickness of the N-type semiconductor layer, it is possible to make the peak sensitivity wavelength in the spectral sensitivity characteristics lie in the visible light wavelength range.

The illuminance sensor chip may comprise a photodiode. In such a case, the distance to the PN junction (which corresponds to the thickness D of the P-type semiconductor layer 34 of FIG. 3) is adjusted so that the peak sensitivity wavelength in the spectral sensitivity characteristics lies in the visible light wavelength range.

1. An illuminance sensor chip comprising a first semiconductor layer, and a second semiconductor layer joined to the first semiconductor layer to provide a junction between the first semiconductor layer and the second semiconductor layer, the sensor chip outputting an electric signal in accordance with an amount of light incident on the junction through the second semiconductor layer;
wherein the second semiconductor layer has a thickness which is set to provide spectral sensitivity characteristics based on the output of the electric signal and having a peak sensitivity wavelength lying in a visible light wavelength range.

2. The illuminance sensor chip according to claim 1, wherein the thickness of the second semiconductor layer is no more than 4 μm.

3. The illuminance sensor chip according to claim 2, wherein the thickness of the second semiconductor layer is no less than 2 μm.

4. The illuminance sensor chip according to claim 1, wherein the peak sensitivity wavelength is 580-600 nm.

5. The illuminance sensor chip according to claim 1, wherein the second semiconductor layer is formed of silicon.

6. The illuminance sensor chip according to claim 1, wherein the illuminance sensor chip is a phototransistor.

7. The illuminance sensor chip according to claim 6, wherein the phototransistor includes an NPN-junction.

8. An illuminance sensor comprising an illuminance sensor chip:
wherein the illuminance sensor chip comprises a first semiconductor layer, and a second semiconductor layer joined to the first semiconductor layer to provide a junction between the first semiconductor layer and the second semiconductor layer, the sensor chip outputting an electric signal in accordance with an amount of light incident on the junction through the second semiconductor layer; and
wherein the second semiconductor layer has a thickness which is set to provide spectral sensitivity characteristics based on the output of the electric signal and having a peak sensitivity wavelength lying in a visible light wavelength range.

9. The illuminance sensor according to claim 8, wherein the second semiconductor layer is formed of silicon and has a thickness of 2-4 μm.

10. The illuminance sensor according to claim 8, wherein the illuminance sensor chip is a phototransistor having an NPN-junction.

11. The illuminance sensor according to claim 8, further comprising:
an additional illuminance sensor chip which is identical or generally identical to the illuminance sensor chip in spectral sensitivity characteristics; and
a visible light shielding portion for absorbing visible light before the incident light reaches the additional sensor chip.

12. The illuminance sensor according to claim 11, wherein the additional illuminance sensor chip is sealed in a black resin package.

13. The illuminance sensor according to claim 11, wherein the illuminance sensor chip is sealed in a first transparent resin package, whereas the additional illuminance sensor chip is sealed in a second black resin package.

14. The illuminance sensor according to claim 13, wherein the first resin package and the second resin package are sealed in a third transparent resin package.

15. An illuminance measuring apparatus comprising:
a first and a second illuminance sensor chips each comprising a first semiconductor layer, and a second semiconductor layer joined to the first semiconductor layer to provide a junction between the first semiconductor layer and the second semiconductor layer, each of the sensor chips outputting an electric signal in accordance with an amount of light incident on the respective junction through the respective second semiconductor layer;
a visible light shielding portion for absorbing visible light before the incident light reaches the junction of the second illuminance sensor chip; and
an illuminance calculation section for calculating an illuminance based on the outputs from the first and the second illuminance sensor chips.

16. The illuminance measuring apparatus according to claim 15, wherein the second semiconductor layer of the first illuminance sensor chip is formed of silicon and has a thickness of 2-4 μm and,
the second illuminance sensor chip is identical or generally identical to the first illuminance sensor chip in spectral sensitivity characteristics.

17. The illuminance measuring apparatus according to claim 15, wherein the illuminance calculation section calculates the illuminance based on a signal corresponding to a difference between the output from the first illuminance sensor chip and the output from the second illuminance sensor chip.

18. An illuminance measuring method using a first and a second illuminance sensor chips:
each of the first and the second illuminance sensor chips comprising a first semiconductor layer, and a second semiconductor layer joined to the first semiconductor layer to provide a junction between the first semiconductor layer and the second semiconductor layer, each of the sensor chips outputting an electric signal in accordance with an amount of light incident on a respective one of the junctions through a respective one of the second semiconductor layers;
the method comprising calculating the illuminance based on the outputs from the first and the second illuminance sensor chips.

19. The illuminance measuring method according to claim 18, wherein the first illuminance sensor chip and the second illuminance sensor chip are identical or generally identical to each other in spectral sensitivity characteristics; and
visible light is absorbed before the incident light reaches the second illuminance sensor chip.

20. The illuminance measuring method according to claim 18, wherein the illuminance is calculated based on a signal corresponding to a difference between the output from the first illuminance sensor chip and the output from the second illuminance sensor chip.
